(19) United States
(12) Patent Application Publication
(10) Pub. No.: US 2024/0290929 A1
(43) Pub. Date: Aug. 29, 2024

(54) DISPLAY APPARATUS AND METHOD FOR MANUFACTURING THE SAME

(71) Applicant: Japan Display Inc., Tokyo (JP)

(72) Inventors: Koichi MIYASAKA, Tokyo (JP); Yoshikatsu IMAZEKI, Tokyo (JP); Yoichi KAMIJO, Tokyo (JP); Shuichi OSAWA, Tokyo (JP); Yoshifumi KAMEI, Tokyo (JP)

(21) Appl. No.: 18/587,096

(22) Filed: Feb. 26, 2024

(30) Foreign Application Priority Data
Feb. 28, 2023 (JP) 2023-030286

(51) Int. Cl. H01L 33/62; H01L 25/075; H01L 33/10

(52) U.S. Cl. CPC H01L 33/62; H01L 25/0753; H01L 33/10; H01L 2933/0066

(57) ABSTRACT

A display apparatus includes a translucent substrate having a first main surface serving as a display surface and a second main surface opposite to the first main surface, a plurality of light-emitting elements provided to the second main surface of the substrate with an adhesive layer interposed between the light-emitting elements and the second main surface, a first terminal and a second terminal provided on a side of each of the light-emitting elements opposite to the substrate, a first protective film covering the light-emitting elements and having a groove between the light-emitting elements adjacent to each other, and a first reflective layer provided to cover the first protective film and having an overlapping portion overlapping the light-emitting element and a side portion provided to a side surface of the groove.

### CROSS-REFERENCE TO RELATED APPLICATION

This application claims the benefit of priority from Japanese Patent Application No. 2023-030286 filed on Feb. 28, 2023, the entire contents of which are incorporated herein by reference.

### BACKGROUND

### 1. Technical Field

The present disclosure relates to a display apparatus and a method for manufacturing the display apparatus.

### 2. Description of the Related Art

Display apparatuses with micro-sized light-emitting diodes (micro LEDs) are provided with a reflective structure to improve the efficiency of light extraction to the display surface side. For example, Japanese Patent Application Laid-open Publication No. 2020-205417 (JP-A-2020-205417) describes a configuration in which a partition wall is provided between a plurality of micro LEDs, and a reflective part is provided on the side surface of the partition wall to reflect light emitted in the direction toward the partition wall. Japanese Patent Application Laid-open Publication No. 2011-166140 (JP-A-2011-166140) describes a light-emitting element package including a light-emitting element chip disposed in a cavity and a reflective layer formed on the surface of the cavity.

Widely known are various configurations for coupling light-emitting diodes to a drive circuit. In U.S. Pat. No. 10,937,815, for example, light-emitting diodes are fixed on an array substrate including thin-film transistors (TFTs) by an adhesive layer. The display apparatus described in U.S. Patent Application Publication No. 2018/0191978 has a module structure in which one pixel includes three light-emitting diodes and a pixel circuit (micro integrated circuit (IC)) coupled to the three light-emitting diodes.

The configurations described in JP-A-2020-205417 and JP-A-2011-166140 have no reflective layer on the back surface side of the light-emitting diodes (side opposite to the display surface). Therefore, it is difficult to extract light output to the back surface side to the display surface side. If the mounting structure of the light-emitting diodes or the coupling configuration with the pixel circuit is different as described in U.S. Pat. No. 10,937,815 and U.S. Patent Application Publication No. 2018/0191978, the reflective structures described in JP-A-2020-205417 and JP-A-2011-166140 may possibly be inapplicable without any change.

### SUMMARY

A display apparatus according to an embodiment of the present disclosure includes a translucent substrate having a first main surface serving as a display surface and a second main surface opposite to the first main surface, a plurality of light-emitting elements provided to the second main surface of the substrate with an adhesive layer interposed between the light-emitting elements and the second main surface, a first terminal and a second terminal provided on a side of each of the light-emitting elements opposite to the substrate, a first protective film covering the light-emitting elements and having a groove between the light-emitting elements adjacent to each other, and a first reflective layer provided to cover the first protective film and having an overlapping portion overlapping the light-emitting element and a side portion provided to a side surface of the groove. The first reflective layer is electrically coupled to the first terminal through a first contact hole formed in the first protective film.

A display apparatus according to an embodiment of the present disclosure includes a translucent substrate having a first main surface serving as a display surface and a second main surface opposite to the first main surface, a plurality of light-emitting elements provided to the second main surface of the substrate, a first terminal and a second terminal provided on a side of each of the light-emitting elements opposite to the substrate, a first reflective layer having an overlapping portion and a side portion, the overlapping portion being provided on the side of the light-emitting element opposite to the substrate and having an opening in a part overlapping the second terminal of the light-emitting element, the side portion facing a side surface of the light-emitting element, a first protective film provided between the light-emitting elements and the first reflective layer, and a second reflective layer overlapping the opening of the first reflective layer. The first reflective layer is electrically coupled to the first terminal through a first contact hole formed in the first protective film, and the second reflective layer is electrically coupled to the second terminal through the opening.

A method for manufacturing a display apparatus according to an embodiment of the present disclosure includes mounting a plurality of light-emitting element on a second main surface of a translucent substrate having a first main surface serving as a display surface and the second main surface opposite to the first main surface with an adhesive layer interposed between the light-emitting elements and the second main surface, forming a first protective film covering the light-emitting elements and forming a groove in the first protective film between the light-emitting elements adjacent to each other, and providing a metal film covering the first protective film, forming a first reflective layer having an overlapping portion overlapping the light-emitting element and a side portion provided to a side surface of the groove, and electrically coupling a first terminal of the light-emitting element to the first reflective layer through a first contact hole formed in the first protective film.

### BRIEF DESCRIPTION OF THE DRAWINGS

FIG. 1 is a plan view schematically illustrating a display apparatus according to an embodiment;

FIG. 2 is a plan view of a pixel of the display apparatus according to the embodiment;

FIG. 3 is a plan view schematically illustrating the arrangement relation between a plurality of light-emitting elements, reflective layers, and a light-shielding layer;

FIG. 4 is a plan view schematically illustrating the arrangement relation between the light-emitting elements, the reflective layers, and a drive circuit without the light-shielding layer illustrated in FIG. 3;

FIG. 5 is a sectional view along line V-V′ of FIG. 3;

FIG. 6 is a sectional view schematically illustrating the display apparatus according to a modification; and

FIG. 7 is a view for explaining a method for manufacturing the display apparatus according to the embodiment.

### DETAILED DESCRIPTION

Exemplary aspects (embodiments) to embody the present disclosure are described below in greater detail with reference to the accompanying drawings. The contents described in the embodiments below are not intended to limit the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the present disclosure and easily conceivable by those skilled in the art naturally fall within the scope of the present disclosure. To simplify the explanation, the drawings may illustrate the width, the thickness, the shape, and other elements of each unit more schematically than an actual aspect. These elements, however, are given by way of example only and are not intended to limit interpretation of the present disclosure. In the present disclosure and the drawings, components similar to those previously described with reference to previous drawings are denoted by like reference numerals, and detailed explanation thereof may be appropriately omitted.

To describe an aspect where a first structure is disposed on a second structure in the present specification and the claims, the term “on” includes both of the following cases unless otherwise noted: a case where the first structure is disposed directly on the second structure in contact with the second structure, and a case where the first structure is disposed on the second structure with another structure interposed therebetween.

### Embodiments

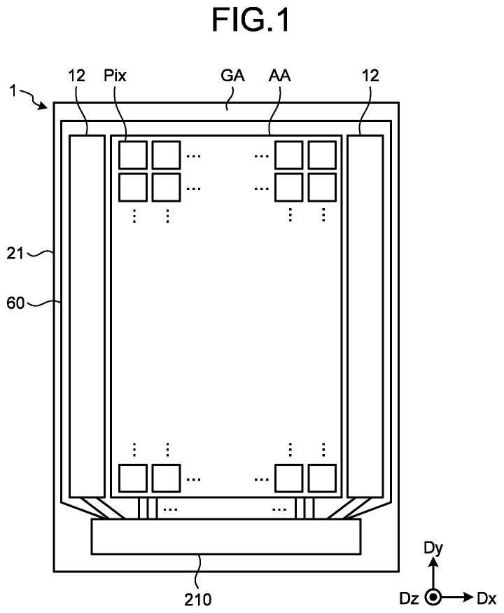

FIG. 1 is a plan view schematically illustrating a display apparatus according to an embodiment. As illustrated in FIG. 1, a display apparatus 1 includes a substrate 21, a plurality of pixels Pix, a scanning circuit 12, a drive integrated circuit (IC) 210, and cathode wiring 60. The substrate 21 is a display substrate that displays images by a plurality of pixel Pix and is provided covering the pixels Pix and peripheral circuits (e.g., the scanning circuit 12 and the drive IC 210). The substrate 21 also serves as a cover substrate (cover glass) that protects the pixels Pix and the peripheral circuits.

As illustrated in FIG. 1, the display apparatus 1 has a display region AA and a peripheral region GA. The display region AA is a region that overlaps the pixels Pix and displays an image. The peripheral region GA is a region not overlapping the pixels Pix and is disposed outside the display region AA.

The pixels Pix are arrayed in a first direction Dx and a second direction Dy in the display region AA of the substrate 21. The first direction Dx and the second direction Dy are parallel to the surface of the substrate 21. The first direction Dx is orthogonal to the second direction Dy. The first direction Dx may intersect the second direction Dy without being orthogonal thereto. A third direction Dz is orthogonal to the first direction Dx and the second direction Dy. The third direction Dz corresponds to the normal direction of the substrate 21, for example. In the following description, plan view refers to the positional relation when viewed from the third direction Dz.

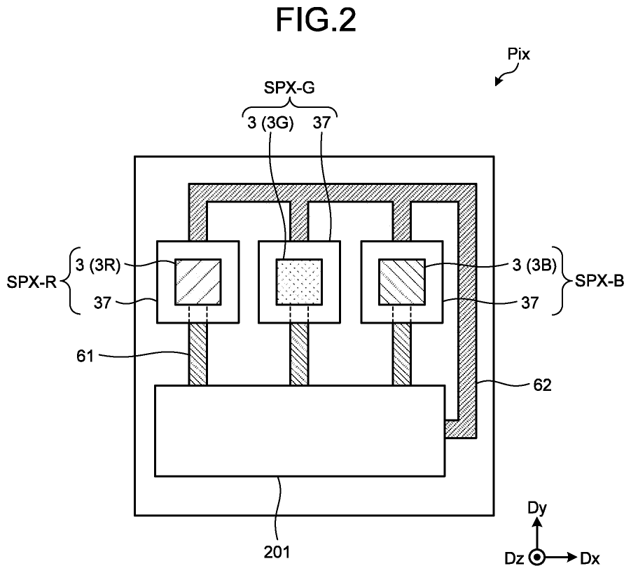

The scanning circuit 12 is a circuit that sequentially selects, row by row, drive circuits 201 (refer to FIG. 2) included in the respective pixels Pix based on various control signals supplied via wiring extending from the drive IC 210. The scanning circuit 12 sequentially or simultaneously selects the drive circuits 201 in each row and supplies control signals to the selected drive circuits 201. As a result, the drive circuits 201 drive light-emitting elements 3 of the pixels Pix.

The drive IC 210 is a circuit that controls display on the display apparatus 1. A plurality of wires (not illustrated) extend from the drive IC 210 toward the drive circuits 201 included in the pixels Pix. The drive IC 210 supplies control signals (pixel signals) to the drive circuits 201 of the respective pixels Pix selected by the scanning circuit 12. The drive circuit 201 supplies drive signals (current) to each light-emitting element 3 due to the control signals from the drive IC 210 and causes the light-emitting element 3 to emit light. The drive IC 210 is mounted in the peripheral region GA of the substrate 21. The present embodiment is not limited thereto, and the drive IC 210 may be mounted on a flexible printed circuit board or a rigid board coupled to the peripheral region GA of the substrate 21.

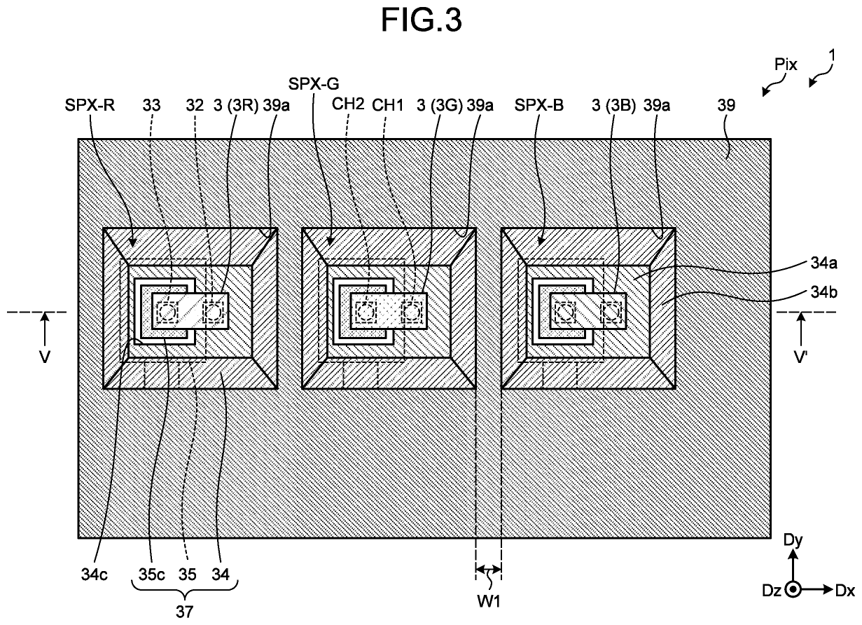

The cathode wiring 60 is provided to the peripheral region GA of the substrate 21. The cathode wiring 60 is provided surrounding the pixels Pix in the display region AA and the scanning circuit 12 in the peripheral region GA. The cathodes of the light-emitting elements 3 are electrically coupled to the common cathode wiring 60 and are supplied with a fixed potential (e.g., a ground potential). More specifically, a cathode terminal 32 (refer to FIG. 3) of the light-emitting element 3 is coupled to the cathode wiring 60 via a cathode electrode 34.

FIG. 2 is a plan view of the pixel of the display apparatus according to the embodiment. As illustrated in FIG. 2, one pixel Pix includes a plurality of pixels SPX and the drive circuit 201. The pixel Pix includes a pixel SPX-R, a pixel SPX-G, and a pixel SPX-B, for example. The pixel SPX-R displays a primary color of red as the first color. The pixel SPX-G displays a primary color of green as the second color. The pixel SPX-B displays a primary color of blue as the third color. As illustrated in FIG. 2, in one pixel Pix, the pixel SPX-R, the pixel SPX-G, and the pixel SPX-B are adjacently disposed in the first direction Dx. The first color, the second color, and the third color are not limited to red, green, and blue, respectively, and may be any desired colors, such as complementary colors. In the following description, the pixel SPX-R, the pixel SPX-G, and the pixel SPX-B are referred to as the pixels SPX when they need not be distinguished from one another.

The pixels SPX each include the light-emitting element 3 and a reflective layer 37. The display apparatus 1 displays an image by causing a light-emitting element 3R, a light-emitting element 3G, and a light-emitting element 3B in the pixel SPX-R, the pixel SPX-G, and the pixel SPX-B, respectively, to output different light. The light-emitting element 3 is an inorganic light-emitting diode (LED) chip having a size of approximately 3 μ m to 300 μ m in plan view and is called a micro LED. The display apparatus 1 including the micro LEDs in the respective pixels is also called a micro LED display apparatus. The term “micro” of the micro LED is not intended to limit the size of the light-emitting element 3.

The light-emitting elements 3 may output light in four or more different colors. The arrangement of the pixels

SPX is not limited to the configuration illustrated in FIG. 2. One pixel SPX, for example, may be disposed side by side with another pixel SPX in the second direction Dy. Alternatively, the pixels SPX may be disposed in a triangular lattice.

The drive circuit 201 is composed of a micro IC, for example, and is provided to each pixel Pix. In the example illustrated in FIG. 2, one drive circuit 201 is provided for three pixels SPX. The drive circuit 201 is coupled to the anode of the light-emitting element 3 of each pixel SPX via wiring 61. The drive circuit 201 is coupled to the cathode of the light-emitting element 3 of each pixel SPX via wiring 62. The drive circuit 201 performs control such that a predetermined current flows through each light- emitting element 3 based on the scanning signals from the scanning circuit 12 and the control signals (pixel signals) from the drive IC 210 as described above, thereby causing the light-emitting element 3 to emit light.

While FIG. 2 illustrates a configuration where one drive circuit 201 is coupled to three light-emitting elements 3, the embodiment is not limited thereto. Alternatively, one drive circuit 201 may be coupled to one light-emitting element 3 or four or more light-emitting elements 3.

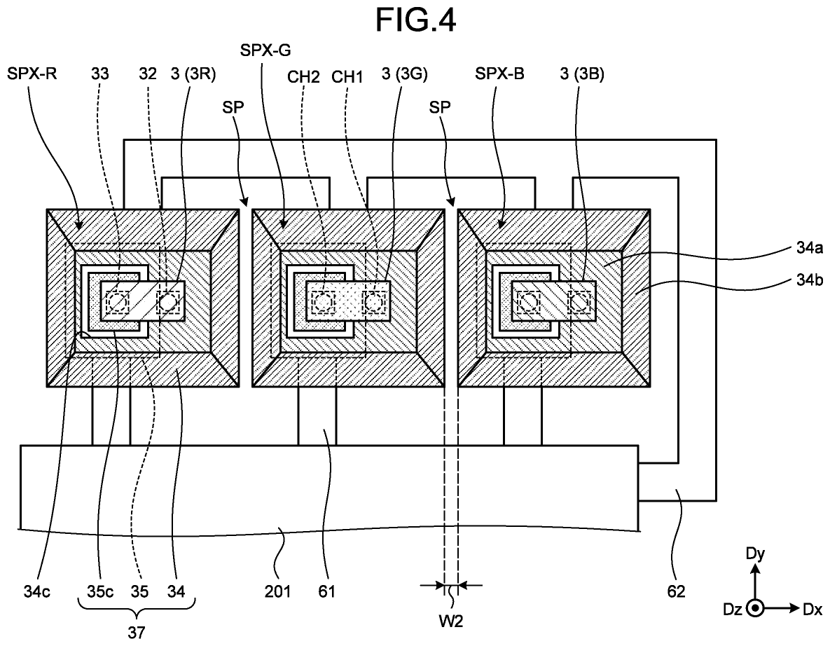

Next, the configuration of the display apparatus 1 is described in detail. FIG. 3 is a plan view schematically illustrating the arrangement relation between a plurality of light-emitting elements, reflective layers, and a light-shielding layer. FIG. 4 is a plan view schematically illustrating the arrangement relation between the light-emitting elements, the reflective layers, and a drive circuit without the light-shielding layer illustrated in FIG. 3.

As illustrated in FIGS. 3 and 4, the pixels SPX-R, SPX-G, and SPX-B include the light-emitting elements 3R, 3G, and 3B, respectively, and each include a cathode electrode 34, an anode electrode 35, and a coupling electrode 35c electrically coupled to the light-emitting elements 3R, 3G, and 3B. The anode electrode 35, the cathode electrode 34, and the coupling electrode 35c are made of metal material and constitute the reflective layer 37 of each of the light-emitting elements 3R, 3G, and 3B. In other words, the anode electrode 35, the cathode electrode 34, and the coupling electrode 35c serve as both the electrodes of the light-emitting elements 3R, 3G, and 3B, and the reflective layer 37.

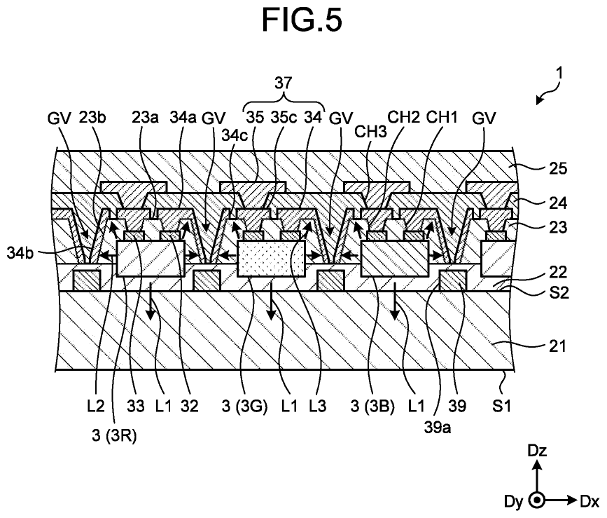

The reflective layer 37 is formed in a cavity shape (recessed shape) when viewed from the display surface (first main surface S1 of the substrate 21 (refer to FIG. 5)). In FIGS. 3 and 4, an overlapping portion 34a and a side portion 34b of the cathode electrode 34 are indicated by different hatching. The overlapping portion 34aoverlaps the light-emitting element 3 and is disposed on the back surface side of the light-emitting element 3 (side opposite to the substrate 21). The side portion 34b is provided around the overlapping portion 34a and faces the side surfaces of the light-emitting element 3. The light-emitting elements 3R, 3G, and 3B are each disposed in the cavity-shaped reflective layer 37. The reflective layer 37 is formed to reflect light output to the side or the back surface side of the light-emitting elements 3R, 3G, and 3B to the first main surface S1 side. The configuration of the reflective layer 37 will be described later in detail with reference to FIG. 5.

As illustrated in FIG. 4, the cathode terminal 32 (first terminal) of the light-emitting element 3 is electrically coupled to the cathode electrode 34 through a first contact hole CH1. The cathode electrode 34 has slits SP between the pixels SPX, whereby a plurality of cathode electrodes 34 are separately provided for the respective light-emitting elements 3 (respective pixels SPX). In other words, a plurality of reflective layers 37 are separately provided for the respective light-emitting elements 3 (respective pixels SPX). The cathode electrodes 34 are coupled to the drive circuit 201 via the common wiring 62.

An anode terminal 33 (second terminal) of the light-emitting element 3 is electrically coupled to the coupling electrode 35c through a second contact hole CH2. The coupling electrode 35c is electrically coupled to the anode electrode 35 through a third contact hole CH3 (refer to FIG. 5). With this configuration, the anode terminal 33 of the light-emitting element 3 is electrically coupled to the anode electrode 35. The anode electrodes 35 are each coupled to the drive circuit 201 via the wiring 61.

As illustrated in FIGS. 3 and 4, A light-shielding layer 39 is provided covering the drive circuit 201 and the wiring 61 and 62. The light-shielding layer 39 has openings 39a in the regions overlapping the light-emitting elements 3 of the respective pixels SPX. The outer periphery of the opening 39a in the light-shielding layer 39 overlaps the outer periphery of the cathode electrode 34. Part of the light-shielding layer 39 is provided between the light-emitting elements 3 (pixels SPX) adjacent to each other in the first direction Dx and extends in the second direction Dy along the outer periphery of the cathode electrode 34. In other words, the light-shielding layer 39 is disposed between the light-emitting elements 3 in plan view seen in a direction perpendicular to the first main surface S1. The width W1 (refer to FIG. 3) of the light-shielding layer 39 between the pixels SPX is larger than the width W2 of the slit SP of the cathode electrode 34.

While FIG. 3 illustrates the light-shielding layer 39 provided to one pixel Pix, the light-shielding layer 39 is continuously provided over a plurality of pixels Pix. The light-shielding layer 39 is provided from the display region AA provided with the pixels Pix to the peripheral region GA and covers the scanning circuit 12 and the drive IC 210 serving as the peripheral circuits, which is not illustrated in the figure.

FIG. 5 is a sectional view along line V-V′ of FIG. 3. As illustrated in FIG. 5, the light-emitting elements 3 are provided on the substrate 21. The substrate 21 has the first main surface S1 serving as the display surface and a second main surface S2 opposite to the first main surface S1. Various electrodes constituting the light-emitting element 3 and the reflective layer 37 are provided on the second main surface S2 of the substrate 21. The second main surface S2 of the substrate 21 is also provided with the drive circuit 201 (refer to FIG. 4) and the wiring 61 and 62 that couples the drive circuit 201 to the light-emitting elements 3, which is not illustrated in the figure. The substrate 21 is a translucent insulating substrate and is a glass or resin substrate, for example.

In the present specification, a direction from the substrate 21 toward the light-emitting element 3 in a direction perpendicular to the surface of the substrate 21 is referred to as an “upper side” or simply as “top”. A direction from the light-emitting element 3 to the substrate 21 is referred to as a “lower side” or simply as “bottom”.

The light-shielding layer 39 is provided on the second main surface S2 of the substrate 21. The light-shielding layer 39 is made of black resin material or a light-blocking metal or alloy film, for example. As described above, the light-shielding layer 39 has the openings 39a in the regions provided with the respective light-emitting elements 3.

An adhesive layer 22 is provided on the second main surface S2 of the substrate 21 to cover the light-shielding layer 39. The adhesive layer 22 is made of optical clear resin (OCR) or an optical clear adhesive film (OCA), for example. The adhesive layer 22 is provided covering the entire second main surface S2 of the substrate 21. The present embodiment is not limited thereto, and the adhesive layer 22 simply needs to be provided at least in the regions provided with the light-emitting elements 3. A plurality of adhesive layers 22 may be separately disposed for the respective openings 39a of the light-shielding layer 39.

A plurality of light-emitting elements 3 are provided on the second main surface S2 of the substrate 21 with the adhesive layer 22 interposed therebetween. While the light-emitting elements 3 may have any desired configuration, they can be each composed of an n-type semiconductor layer, an active layer, and a p-type semiconductor layer stacked in this order. The semiconductor layer is made of compound semiconductor, such as gallium nitride (GaN), aluminum indium phosphorous (AlInP), and indium gallium nitride (InGaN). The semiconductor layer may be made of different materials for the respective light-emitting elements 3R, 3G, and 3B. The active layer may have a multi-quantum well structure (MQW structure) in which well layers and barrier layers composed of several atomic layers are cyclically stacked for higher efficiency.

The cathode terminal 32 and the anode terminal 33 are provided on the side of the light-emitting element 3 opposite to the substrate 21. More specifically, the cathode terminal 32 and the anode terminal 33 are provided on the same surface of the light-emitting element 3, which is the surface opposite to the surface facing the second main surface S2 of the substrate 21. In other words, the light-emitting elements 3 are each disposed such that the surface not provided with the cathode terminal 32 or the anode terminal 33 faces the second main surface S2 of the substrate 21 and are provided on the second main surface S2 with the adhesive layer 22 interposed therebetween.

A first protective film 23 is provided covering the light-emitting elements 3. More specifically, the first protective film 23 is provided covering at least part of the upper surface and the side surfaces of the light-emitting elements 3 and has the first contact hole CH1 and the second contact hole CH2 in the regions overlapping the cathode terminal 32 and the anode terminal 33, respectively. The first protective film 23 is an organic insulating film and is made of organic material, such as photosensitive acrylic. The organic material, such as photosensitive acrylic, is excellent in coverability for level difference caused by the light-emitting elements 3 and in surface flatness compared with inorganic insulating material formed by CVD, for example.

The first protective film 23 has grooves GV formed between the light-emitting elements 3 adjacent to each other. The groove GV passes through the upper and lower surfaces of the first protective film 23 and has a tapered shape that decreases in width as closer to the second main surface S2 of the substrate 21. The bottom of the groove GV is disposed at the position overlapping the light-shielding layer 39. While FIG. 5 illustrates the grooves GV formed between the light-emitting elements 3 adjacent to each other in the first direction Dx, the grooves GV are also formed between the light-emitting elements 3 adjacent to each other in the second direction Dy. The groove GV is formed around one light-emitting element 3 in plan view.

In other words, the first protective film 23 is formed in an island shape for each of the light-emitting elements 3 with the grooves GV interposed therebetween. The first protective film 23 covering each of the light-emitting elements 3 has a tapered shape that increases in width as closer to the second main surface S2 of the substrate 21. The side surfaces of the first protective film 23 are inclined in a direction of widening toward the second main surface S2 of the substrate 21.

The cathode electrode 34 (first reflective layer) and the coupling electrode 35c are provided covering the first protective film 23. The cathode electrode 34 includes the overlapping portion 34a that overlaps the light-emitting element 3 and the side portion 34b provided on the side surfaces of the grooves GV. The slit SP (refer to FIG. 4) of the cathode electrode 34 is formed at the bottom of the groove GV. In other words, the slit SP overlaps the light-shielding layer 39. More specifically, the overlapping portion 34a of the cathode electrode 34 is disposed facing the upper surface of the light-emitting element 3 (surface provided with the cathode terminal 32 and the anode terminal 33), and the side portion 34b of the cathode electrode 34 is disposed facing the side surfaces of the light-emitting element 3. The overlapping portion 34a of the cathode electrode 34 is coupled to the cathode terminal 32 through the first contact hole CH1 formed in the first protective film 23.

The overlapping portion 34a of the cathode electrode 34 has an opening 34c in the region overlapping the anode terminal 33. The coupling electrode 35c is provided in the region overlapping the opening 34c on the first protective film 23. The coupling electrode 35c is provided in the same layer as that of the overlapping portion 34a of the cathode electrode 34 in a manner separated from the overlapping portion 34a of the cathode electrode 34 with a gap interposed therebetween. The coupling electrode 35c is coupled to the anode terminal 33 through the second contact hole CH2 formed in the first protective film 23.

A second protective film 24 is provided on the first protective film 23 to cover the cathode electrodes 34 (first reflective layer) and the coupling electrodes 35c. The second protective film 24 is made of an organic insulating film. The second protective film 24 is provided to fill the inside of the grooves GV and has a flat upper surface.

The anode electrode 35 (second reflective layer) is provided on the second protective film 24 and is coupled to the coupling electrode 35c through the third contact hole CH3 formed in the second protective film 24. The anode electrode 35 has a larger area than the opening 34c of the cathode electrode 34 in plan view and is provided in the region overlapping the opening 34c of the cathode electrode 34. In other words, the anode electrode 35 is provided in the region overlapping the gap between the cathode electrode 34 and the coupling electrode 35c.

The cathode electrode 34, the anode electrode 35, and the coupling electrode 35c are made of metal material, such as titanium (Ti) and aluminum (Al). The cathode electrode 34, the anode electrode 35, and the coupling electrode 35c may be a multilayered film of Ti/Al/Ti, for example. The cathode electrode 34 and the coupling electrode 35c are formed in the same process and made of the same material. The cathode electrode 34 and the anode electrode 35 may be made of the same material or different materials.

A third protective film 25 is provided on the second protective film 24 to covers the anode electrodes 35. The third protective film 25 is made of an organic insulating film like the first protective film 23 and the second protective film 24. The third protective film 25, however, may be an inorganic insulating film. At least one of the first protective film 23, the second protective film 24, and the third protective film 25 may be a multilayered film composed of an organic insulating film and an inorganic insulating film.

With this configuration, the reflective layer 37 is composed of the cathode electrode 34, the anode electrode 35, and the coupling electrode 35c. The reflective layer 37 is formed in a cavity shape when viewed from the first main surface S1 of the substrate 21, and each light-emitting element 3 is disposed in a manner surrounded by the cavity-shaped cathode electrode 34. Light L1 output from the light-emitting element 3 toward the substrate 21 is transmitted through the first main surface S1 of the substrate 21 and is visually recognized as a display image.

Light L2 output from the light-emitting element 3 toward the side is reflected by the side portion 34b of the cathode electrode 34 (first reflective layer) and is output toward the first main surface S1 of the substrate 21. Light L3 output from the light-emitting element 3 toward the back surface side is reflected by the overlapping portion 34a of the cathode electrode 34 (first reflective layer) and is output toward the first main surface S1 of the substrate 21. Light that has passed through the opening 34c of the cathode electrode 34 (gap between the cathode electrode 34 and the coupling electrode 35c) in the light L3 output from the light-emitting element 3 toward the back surface side is reflected by the anode electrode 35 (second reflective layer). Part of the reflected light passes through the opening 34c of the cathode electrode 34 and returns to the first main surface S1 side of the substrate 21. With this configuration, the display apparatus 1 according to the present embodiment can improve the light extraction efficiency.

The light-shielding layer 39 is provided between the end of the side portion 34b of the cathode electrode 34 on the second main surface S2 side and the second main surface S2 of the substrate 21 in the third direction Dz and between the side portions 34b of the cathode electrodes 34 adjacent to each other in plan view. With this configuration, part of light reflected in an oblique direction by the reflective layer 37 and traveling toward an adjacent pixel SPX is absorbed by the light-shielding layer 39. Therefore, the display apparatus 1 according to the present embodiment can improve the light extraction efficiency and suppress color mixture between the pixels SPX adjacent to each other.

The cathode electrode 34, the anode electrode 35, and the coupling electrode 35c serve not only as the electrodes that electrically couple the light-emitting element 3 to the drive circuit 201 (refer to FIG. 4) but also as the reflective layer 37. Therefore, the display apparatus 1 requires a smaller number of layers and has a simpler multilayered structure than a case where the reflective layer 37 is provided in another layer different from that of the various electrodes.

The configuration of the electrodes (reflective layer 37) illustrated in FIGS. 2 to 5 is given by way of example only and can be appropriately modified. For example, the cathode electrode 34 and the anode electrode 35 may be interchanged. In other words, the anode electrode 35 (first reflective layer) may be provided covering the first protective film 23, and the cathode electrode 34 (second reflective layer) may be provided on the second protective film 24 provided covering the anode electrode 35.

### Modifications

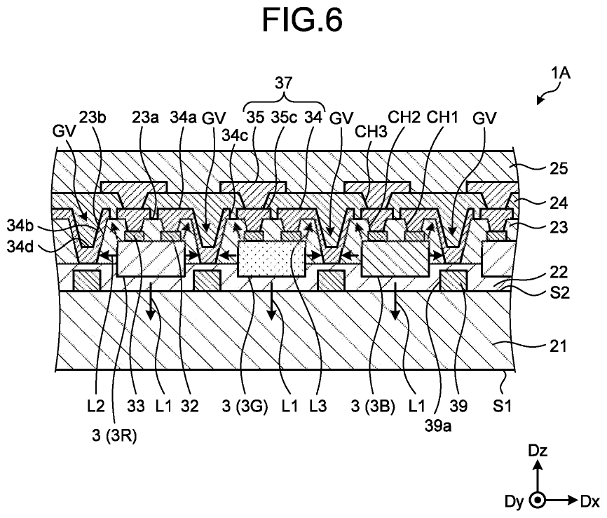

FIG. 6 is a sectional view schematically illustrating the display apparatus according to a modification. In the following description, the same components as those described in the embodiment above are denoted by like reference numerals, and overlapping explanation thereof is omitted.

As illustrated in FIG. 6, in a display apparatus 1A according to the modification, the cathode electrode 34 (first reflective layer) is provided on the side surfaces and the bottom of the groove CV and is continuously provided over a plurality of light-emitting elements 3. In other words, the cathode electrode 34 is provided over a plurality of pixels SPX and supplies a cathode potential serving as a common potential to the cathode terminals 32 of the respective light-emitting elements 3. In the present modification, it is not necessary to form the slit SP (refer to FIG. 4) of the cathode electrode 34. This configuration can improve the flexibility in drawing the wiring 62 (refer to FIG. 4) that couples the cathode electrodes 34 of the light-emitting elements 3 to the drive circuit 201.

### Manufacturing Method

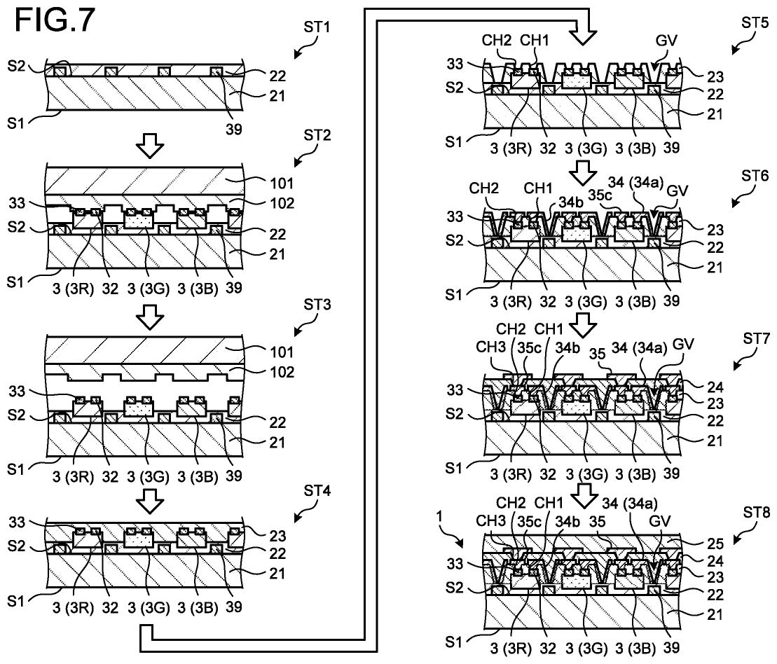

FIG. 7 is a view for explaining a method for manufacturing the display apparatus according to the embodiment. As illustrated in FIG. 7, the method for manufacturing the display apparatus 1A according to the embodiment is as follows: the translucent substrate 21 having the first main surface S1 serving as the display surface and the second main surface S2 opposite to the first main surface S1 is prepared first, and the light-shielding layer 39 is formed on the second main surface S2 and is subjected to patterning to form the openings for the respective pixels SPX. The adhesive layer 22 is applied and formed on the second main surface S2 of the substrate 21 to cover the light-shielding layer 39 (Step ST1).

Subsequently, the light-emitting elements 3R, 3G, and 3B arrayed on a transfer substrate 101 with an adhesive layer 102 interposed therebetween are prepared. The light-emitting elements 3R, 3G, and 3B are formed on different sapphire substrates and are transferred from the respective sapphire substrates onto the common transfer substrate 101 by a laser lift-off method, for example. The light-emitting elements 3R, 3G, and 3B on the transfer substrate 101 are disposed corresponding to the array of the pixels SPX. The light-emitting elements 3R, 3G, and 3B are disposed such that the surface not provided with the cathode terminal 32 or the anode terminal 33 faces the second main surface S2 of the substrate 21, and the light-emitting elements 3R, 3G, and 3B are temporarily bonded to the adhesive layer 22 (Step ST2).

The adhesive layer 22 is cured by ultraviolet irradiation or other methods, and the light-emitting elements 3R, 3G, and 3B are fixed to the second main surface S2 of the substrate 21. Subsequently, the transfer substrate 101 is peeled off. Thus, the light-emitting elements 3R, 3G, and 3B are mounted on the second main surface S2 of the substrate 21 with the adhesive layer 22 interposed therebetween (Step ST3).

Subsequently, the first protective film 23 is applied and formed to cover the light-emitting elements 3 (Step ST4). The first protective film 23 is made of photosensitive material, such as acrylic resin. The first protective film 23 is formed to cover the upper surface (the cathode terminal 32 and the anode terminal 33) and the side surfaces of the light-emitting elements 3 and to flatten the unevenness of the light-emitting elements 3.

Subsequently, the first contact holes CH1, the second contact holes CH2, and the grooves GV are formed in the first protective film 23 by photolithography and etching (Step ST5). The first contact hole CH1 and the second contact hole CH2 are formed in the regions overlapping the cathode terminal 32 and the anode terminal 33, respectively, of the light-emitting element 3. The groove GV is formed in the first protective film 23 between the light-emitting elements 3 adjacent to each other. In other words, the groove GV is formed in the region overlapping the light-shielding layer 39.

Subsequently, a metal film is formed to cover the first protective film 23 and the grooves GV and is subjected to patterning. Thus, the cathode electrodes 34 (first reflective layer) each having the overlapping portion 34a overlapping the light-emitting element 3 and the side portion 34b provided on the side surfaces of the grooves GV are formed (Step ST6). In the process of patterning the metal film, the coupling electrodes 35c are formed in the same layer as that of the overlapping portions 34a of the cathode electrodes 34. The overlapping portion 34a of the cathode electrode 34 is electrically coupled to the cathode terminal 32 through the first contact hole CH1 formed in the first protective film 23. The coupling electrode 35c is electrically coupled to the anode terminal 33 through the second contact hole CH2 formed in the first protective film 23.

Subsequently, the second protective film 24 and the anode electrodes 35 (second reflective layer) are formed (Step ST7). More specifically, the second protective film 24 is made of photosensitive material, such as acrylic resin. The second protective film 24 is provided to cover the cathode electrodes 34, the coupling electrodes 35c, and the first protective films 23 and is formed to flatten the grooves GV. Subsequently, the third contact holes CH3 are formed in the regions overlapping the respective coupling electrodes 35c in the second protective film 24 by photolithography and etching.

A metal film is formed to cover the first protective film 23 and the third contact holes CH3 and is subjected to patterning. Thus, the anode electrodes 35 are formed in the regions overlapping the respective openings 34c of the cathode electrodes 34. The anode electrode 35 is electrically coupled to the coupling electrode 35c through the third contact hole CH3 formed in the second protective film 24.

Subsequently, the third protective film 25 is formed on the second protective film 24 to cover the anode electrodes 35 (Step ST8). The third protective film 25 is made of an organic insulating film like the first protective film 23 and the second protective film 24. The third protective film 25 may be made of an inorganic insulating film or a multilayered film composed of an organic insulating film and an inorganic insulating film.

As described above, the method for manufacturing the display apparatus 1 according to the present embodiment mounts the light-emitting elements 3 on the substrate 21 serving as the display substrate with the adhesive layer 22 interposed therebetween. In the display apparatus 1, the cathode electrode 34, the anode electrode 35, and the coupling electrode 35c are formed in a cavity shape to cover the light-emitting element 3 and also satisfactorily function as the reflective layer 37.

While exemplary embodiments according to the present disclosure have been described, the embodiments are not intended to limit the present disclosure. The contents disclosed in the embodiments are given by way of example only, and various modifications may be made without departing from the spirit of the present disclosure. Appropriate modifications made without departing from the spirit of the present disclosure naturally fall within the technical scope of the present disclosure. At least one of various omissions, substitutions, and modifications of the components may be made without departing from the gist of the embodiments above and the modifications thereof.

What is claimed is:

1. A display apparatus comprising:
a translucent substrate having a first main surface serving as a display surface and a second main surface opposite to the first main surface;
a plurality of light-emitting elements provided to the second main surface of the substrate with an adhesive layer interposed between the light-emitting elements and the second main surface;
a first terminal and a second terminal provided on a side of each of the light-emitting elements opposite to the substrate;
a first protective film covering the light-emitting elements and having a groove between the light-emitting elements adjacent to each other; and
a first reflective layer provided to cover the first protective film and having an overlapping portion overlapping the light-emitting element and a side portion provided to a side surface of the groove, wherein
the first reflective layer is electrically coupled to the first terminal through a first contact hole formed in the first protective film.

2. The display apparatus according to claim 1, further comprising:
a second protective film provided on the first protective film to cover the first reflective layer; and
a second reflective layer provided on the second protective film; wherein the overlapping portion of the first reflective layer has an opening formed in a region overlapping the second terminal,
a coupling electrode is provided in a region where the opening of the overlapping portion is formed in the first protective film, and
the second reflective layer is provided covering a gap between the coupling electrode and the overlapping portion.

3. The display apparatus according to claim 2, wherein the coupling electrode is electrically coupled to the second terminal through a second contact hole formed in the first protective film, and the second reflective layer is electrically coupled to the coupling electrode through a third contact hole formed in the second protective film.

4. The display apparatus according to claim 1, further comprising:
a light-shielding layer provided to the second main surface of the substrate and disposed between the light- emitting elements in plan view seen in a direction perpendicular to the substrate, wherein
a bottom of the groove is provided overlapping the light-shielding layer, and
the light-shielding layer is disposed between the second main surface of the substrate and an end of the side portion of the first reflective layer on the second main surface side in the direction perpendicular to the substrate.

5. The display apparatus according to claim 1, wherein the first reflective layer is separately provided for each of the light-emitting elements by a slit formed at a bottom of the groove.

6. The display apparatus according to claim 5, further comprising:
a light-shielding layer provided to the second main surface of the substrate and disposed between the light-emitting elements in plan view seen in a direction perpendicular to the second main surface, wherein
the slit of the first reflective layer is formed overlapping the light-shielding layer, and
the width of the light-shielding layer disposed between the light-emitting elements is larger than the width of the slit of the first reflective layer.

7. The display apparatus according to claim 4, wherein the first reflective layer is provided to a side surface and a bottom of the groove and is continuously provided over the light-emitting elements.

8. The display apparatus according to claim 2, wherein the first reflective layer is a cathode electrode, and the second reflective layer is an anode electrode.

9. The display apparatus according to claim 2, wherein the first reflective layer is an anode electrode, and the second reflective layer is a cathode electrode.

10. A display apparatus comprising:
a translucent substrate having a first main surface serving as a display surface and a second main surface opposite to the first main surface;
a plurality of light-emitting elements provided to the second main surface of the substrate;
a first terminal and a second terminal provided on a side of each of the light-emitting elements opposite to the substrate;
a first reflective layer having an overlapping portion and a side portion, the overlapping portion being provided on the side of the light-emitting element opposite to the substrate and having an opening in a part overlapping the second terminal of the light-emitting element, the side portion facing a side surface of the light-emitting element;
a first protective film provided between the light-emitting elements and the first reflective layer; and
a second reflective layer overlapping the opening of the first reflective layer, wherein
the first reflective layer is electrically coupled to the first terminal through a first contact hole formed in the first protective film, and
the second reflective layer is electrically coupled to the second terminal through the opening.

11. A method for manufacturing a display apparatus comprising:
mounting a plurality of light-emitting elements on a second main surface of a translucent substrate having a first main surface serving as a display surface and the second main surface opposite to the first main surface with an adhesive layer interposed between the light-emitting elements and the second main surface;
forming a first protective film covering the light-emitting elements and forming a groove in the first protective film between the light-emitting elements adjacent to each other; and
providing a metal film covering the first protective film, forming a first reflective layer having an overlapping portion overlapping the light-emitting element and a side portion provided to a side surface of the groove, and electrically coupling a first terminal of the light-emitting element to the first reflective layer through a first contact hole formed in the first protective film.
